(19) United States
(12) Patent Application Publication
(10) Pub. No.: US 2011/0079872 A1
(43) Pub. Date: Apr. 7, 2011

(54) PASSIVE DEVICE, SEMICONDUCTOR MODULE, ELECTRONIC CIRCUIT BOARD, AND ELECTRONIC SYSTEM HAVING THE PASSIVE DEVICE, AND METHODS OF FABRICATING AND INSPECTING THE SEMICONDUCTOR MODULE

(75) Inventors: Seong-Chan HAN, Cheonan-si (KR); Jin-Kyu Yang, Seoul (KR); Jae-Young Kim, Suwon-si (KR); Kwang-Su Yu, Cheonan-si (KR)

(73) Assignee: Samsung Electronics Co., Ltd, Suwon-si (KR)

(21) Appl. No.: 12/772,351

(22) Filed: May 3, 2010

(30) Foreign Application Priority Data
Oct. 6, 2009 (KR) 2009-0094833

(51) Int. Cl. H01L 29/86

(52) U.S. Cl. 257/528; 257/E29.325

(57) ABSTRACT

Provided are a passive device of a semiconductor module, a semiconductor module having the passive device, an electronic circuit board and electronic system having the passive device or semiconductor module, and methods of fabricating and inspecting the semiconductor module. The passive device of the semiconductor module includes a main body and at least two real electrodes disposed on one lateral surface of the main body.

### CROSS-REFERENCE TO RELATED APPLICATIONS

This application claims the benefit of priority under 35 U.S.C. §119 from Korean Patent Application No. 10-2009-0094833, filed on Oct. 6, 2009, the contents of which are hereby incorporated herein by reference in its entirety.

### BACKGROUND

1. Field of the Invention

Example embodiments relate to a passive device of a semiconductor module, a semiconductor module having the same, an electronic circuit board and an electronic system having the passive device or the semiconductor module, and methods of fabricating and inspecting the semiconductor module.

2. Description of the Related Art

In order to improve the integration densities of semiconductor modules, electronic circuit boards, and electronic systems, methods for increasing the integration densities of the semiconductor modules and electronic circuit boards are being required, in addition to a method of reducing the size of a semiconductor chip.

### SUMMARY

Example embodiments of the present general inventive concept provide a passive device that may be mounted on a semiconductor module.

Additional features and utilities of the present general inventive concept will be set forth in part in the description which follows and, in part, will be obvious from the description, or may be learned by practice of the general inventive concept.

Also, example embodiments of the present general inventive concept provide a semiconductor module including a passive device.

In addition, example embodiments of the present general inventive concept provide an electronic circuit board including a passive device or a semiconductor module.

Furthermore, example embodiments of the present general inventive concept provide an electronic system including a passive device or a semiconductor module.

Moreover, example embodiments of the present general inventive concept provide a method of fabricating a semiconductor module including a passive device.

Also, example embodiments of the present general inventive concept provide a method of fabricating a semiconductor module.

Features and utilities of the present general inventive concept should not be limited by the above description, and other unmentioned aspects will be clearly understood by one of ordinary skill in the art from example embodiments described herein.

Example embodiments of the present general inventive concept may provide a passive device of a semiconductor module includes: a main body, and at least two real electrodes disposed on one lateral surface of the main body.

Example embodiments of the present general inventive concept may also provide a passive device of a semiconductor module that includes a main body, at least two real electrodes disposed on one lateral surface of the main body, each real electrode having a fillet shape, and at least one dummy electrode disposed on another lateral surface of the main body disposed opposite the one lateral surface thereof, each dummy electrode having a fillet shape. The real electrodes are electrically connected to one another, and the dummy electrode is not electrically connected to the real electrodes.

Example embodiments of the present general inventive concept may also provide a passive device of a semiconductor module that includes a main body, at least three real electrodes disposed on one lateral surface of the main body, each real electrode having a fillet shape, and at least one dummy electrodes disposed on another lateral surface of the main body disposed opposite the one lateral surface thereof, each dummy electrode having a filet shape. Two of the real electrodes are electrically connected to each other, and the dummy electrode is not electrically connected to the real electrodes.

Example embodiments of the present general inventive concept may also provide a semiconductor module that includes a module substrate, conductive module interconnections disposed on the module substrate, a solder disposed on a portion of at least one of the conductive module interconnections, a semiconductor package disposed on the module substrate and electrically connected to the module interconnections through the solder, and a passive device interleaved between the module substrate and the semiconductor package. The passive device includes a main body, and at least two real electrodes disposed on one lateral surface of the main body.

Example embodiments of the present general inventive concept also provide an electronic circuit board includes a base board, and a main processing circuit, a sub-processing circuit, and a memory circuit disposed on the base board. The memory circuit includes at least one semiconductor module, the semiconductor module includes at least one passive device, and the passive device includes a main body and at least two real electrodes disposed on one lateral surface of the main body.

Example embodiments of the present general inventive concept also provide an electronic system includes a central processing unit (CPU), a memory unit, an input unit, and an output unit. The memory unit includes at least one semiconductor module, the semiconductor module includes at least one passive device, and the passive device includes a main body and at least two real electrodes disposed on one lateral surface of the main body.

Example embodiments of the present general inventive concept also provide a method of fabricating a semiconductor module that includes preparing a module substrate, forming first and second solders on the module substrate, and bonding a passive device onto the first solders and bonding a semiconductor package onto the second solders. The passive device includes a main body and at least two real electrodes disposed on one lateral surface of the main body.

Example embodiments of the present general inventive concept also provide a method of inspecting a semiconductor module includes forming a semiconductor package on a module substrate, and visually inspecting a semiconductor module having a passive device interleaved between the module substrate and the semiconductor package using an optical apparatus. The passive device includes at least two real electrodes disposed toward an outer portion of the semiconductor package.

Example embodiments of the present general inventive concept may also provide a method of inspecting a semiconductor module, where visually inspecting the semiconductor module includes reflecting light from at least one lateral surface of the passive device with a reflective device to a light receiving unit, and inspecting a connection state of the at least two real electrode of the passive device with the light receiving unit.

Example embodiments of the present general inventive concept may also provide a passive device of a semiconductor module, including a main body, and a plurality of real electrodes disposed in channels of a first surface of the main body and electrically connected to one another.

The passive device may include at least one dummy electrode disposed in the at least one channel of a second surface of the main body that is opposite the first surface, where the at least one dummy electrode is not electrically connected to the plurality of real electrodes.

Example embodiments of the present general inventive concept may also provide a semiconductor module, including a module substrate, conductive module interconnections disposed on the module substrate, at least one passive solder device disposed on at least one of the conductive module interconnections, at least one passive device having a main body and a plurality of real electrodes disposed in channels of a surface of the main body, the main body disposed on the at least one passive solder device, and a semiconductor package disposed on the module substrate and electrically connected to the module interconnections at least through a solder.

Features and utilities of the present general inventive concept should not be limited by the above description but may be proposed by the following description and drawings.

Specific particulars of other example embodiments of the present general inventive concept are included in the detailed description and drawings.

### BRIEF DESCRIPTION OF THE DRAWINGS

Example embodiments are described in further detail below with reference to the accompanying drawings. It should be understood that various aspects of the drawings may have been exaggerated for clarity.

The above and/or other features and utilities of the present general inventive concept will become apparent and more readily appreciated from the following description of the exemplary embodiments, taken in conjunction with the accompanying drawings, in which:

FIGS. 1A through 1D illustrate schematic perspective views of passive devices according to example embodiments of the present general inventive concept;

FIG. 2A illustrates a conceptual plan view of a semiconductor module according to example embodiments of the present general inventive concept, and FIG. 2B is an enlarged view illustrating region A of the semiconductor module of FIG. 2A;

FIGS. 3A and 3B illustrate longitudinal sectional views taken along lines I-I′ and II-II′ of FIG. 2B, respectively;

FIG. 4 illustrates a block diagram of an electronic circuit board according to example embodiments of the present general inventive concept;

FIG. 5 illustrates a block diagram of an electronic system according to example embodiments of the present;

FIGS. 6A through 6E are schematic diagrams illustrating a method of fabricating a semiconductor module according to example embodiments; and

FIG. 7 is a longitudinal sectional view illustrating a process operation of a method of inspecting a semiconductor module according to example embodiments of the present general inventive concept.

### DETAILED DESCRIPTION OF THE EMBODIMENTS

Various example embodiments will now be described more fully with reference to the accompanying drawings in which some example embodiments are illustrated. The present general inventive concept may, however, be embodied in different forms and should not be construed as limited to the embodiments set forth herein. Rather, these embodiments are provided so that this disclosure is thorough and complete and fully conveys the scope of the inventive concept to one skilled in the art. In the drawings, the thicknesses of layers and regions may be exaggerated for clarity. Like numbers refer to like elements throughout. In the present specification, example embodiments will be described with reference to idealized schematic plan and cross-sectional views. Thus, the shapes of example diagrams may be modified according to fabrication techniques and/or tolerances. Accordingly, example embodiments should not be limited to specific shapes and may include modified shapes according to fabrication processes. Respective components illustrated in the drawings included in the present specification should not be limited to absolute shapes and sizes and may be exaggerated or simplified for brevity. In the present specification, singular forms of respective components should be interpreted as having a meaning of “at least one” and should not be construed as being limited to “only one.” Also, plural forms of respective components should be interpreted as including the meaning of “at least one.” In the present specification, a term “passive device” may be interpreted as a relative concept of a term “active device.” That is, the term “passive device” may be interpreted as a device without a transistor. It will be further understood that electrical connection should be interpreted either as a physical contact between resistors, reactors, or interconnections or as electrical interlocking between capacitors without a physical contact. The specific particulars of other example embodiments are included in the detailed description and drawings.

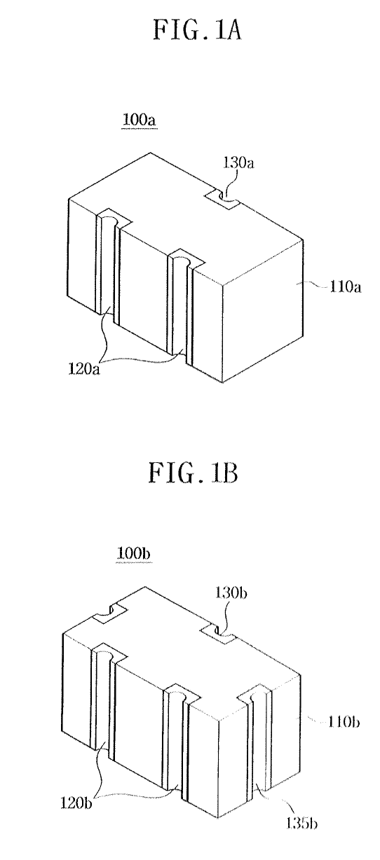

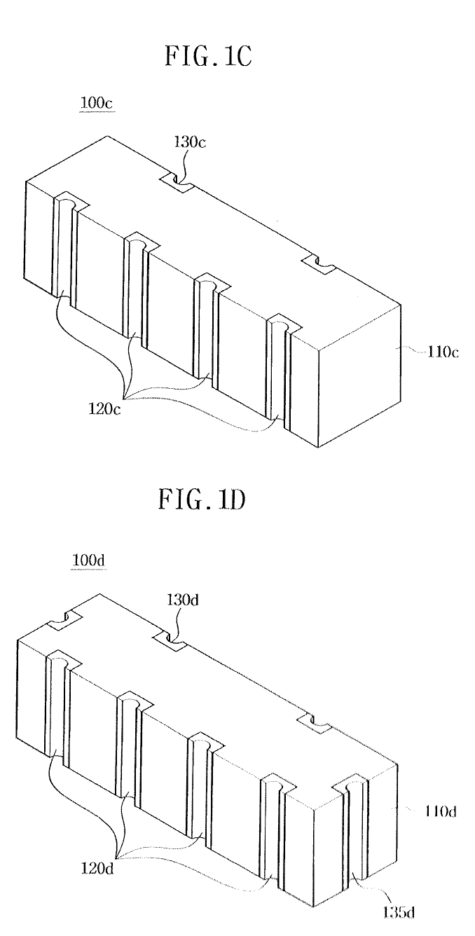

FIGS. 1A through 1D illustrate schematic perspective views of passive devices according to exemplary embodiments of the present inventive concept. Referring to FIG. 1A, a passive device 100a according to the present general inventive concept may include a main body 110a and at least two real electrodes 120a disposed on a first lateral surface of the main body 110a. The real electrodes 120a may be used to transmit electrical signals. Specifically, one of the real electrodes 120a may be an input electrode, and another electrode may be an output electrode. The real electrodes 120a may be electrically connected to one another within the main body 110a. The main body 110a may include at least one first dummy electrode 130a. The first dummy electrode 130a may be disposed on a second lateral surface of the main body 110a, which is disposed opposite the first lateral surface on which the real electrodes 120a are disposed. The first dummy electrode 130a may have the same outward shape as the real electrodes 120a. The first dummy electrode 130a may be electrically insulated from the real electrodes 120a. In other words, the first dummy electrodes 130a may be electrically floated. Although FIG. 1A illustrates only one first dummy electrode 130a, a plurality of first dummy electrodes 130a may be provided. The real electrodes 120a and the first dummy electrode 130a may be formed of copper (Cu) and have surfaces plated with tin (Sn) and titanium nitride.

Referring to FIG. 1B, a passive device 100b according to exemplary embodiments of the present general inventive concept may include a main body 110b and at least two real electrodes 120b disposed on a first lateral surface of the main body 110b. The passive device 100b may further include at least one second dummy electrode 135b disposed on a second lateral surface of the main body 110b other than the first lateral surface on which the real electrodes 120b are disposed. The passive device 100b may include at least two second dummy electrodes 135b. The at least two second dummy electrodes 135b may be disposed opposite each other. The main body 110b may include at least one first dummy electrode 130b. The first dummy electrode 130b may be disposed on a second lateral surface of the main body 110b, which is disposed opposite the first lateral surface on which the real electrodes 120b are disposed. The first dummy electrode 130b may have the same outward shape as the real electrodes 120b. The first dummy electrode 130b may be electrically insulated from the real electrodes 120b. In other words, the first dummy electrodes 130b may be electrically floated. A single second dummy electrode 135b may be formed on one lateral surface of the main body 110b or each of two lateral surfaces of the main body 110b. Alternatively, a plurality of second dummy electrodes 135b may be formed on one lateral surface of the main body 110b.

Referring to FIG. 1C, a passive device 100c according to example embodiments of the present general inventive concept may include a main body 110c and at least four real electrodes 120c disposed on a lateral surface of the main body 110c. When the passive device 110c includes the at least four real electrodes 120c, one main body 110c can include at least two unit passive devices. When the unit passive devices included in the main body 110c are not electrically connected to one another, two of the four real electrodes 120c may be input electrodes of the respective unit passive devices, while the remaining two may be output electrodes thereof. When the unit passive devices included in the main body 110c are electrically connected to one another, one to three of the four real electrodes 120c may be common input electrodes or common output electrodes of the unit passive devices. The main body 110c may include at least one first dummy electrode 130c.

Referring to FIG. 1D, a passive device 100d according to example embodiments of the present general inventive concept may include a main body 110d and at least two real electrodes 120d disposed on a first lateral surface of the main body 110d. The passive device 100d may further include at least one second dummy electrode 135d disposed on a second lateral surface of the main body 110d other than the first lateral surface on which the real electrodes 120d are disposed. The passive device 100d may include at least two second dummy electrodes 135d. In this case, the at least two second dummy electrodes 130d may be disposed opposite each other. A single second dummy electrode 135d may be disposed on one lateral surface of the main body 110d or each of two lateral surfaces thereof. Alternatively, a plurality of second dummy electrodes 135d may be disposed on one lateral surface of the main body 110d.

The passive devices 110a to 110d according to example embodiments of the present general inventive concept may respectively include the real electrodes 120a to 120d disposed on first lateral surfaces thereof and the first dummy electrodes 130a to 130d disposed on second lateral surfaces disposed opposite the first lateral surfaces. Second dummy electrodes 135b and 135d may be formed on at least one of lateral surfaces other than the first and second lateral surfaces on which the real electrodes 120a to 120d and the first dummy electrodes 130a to 130d are disposed. According to example embodiments of the present general inventive concept, the real electrodes 120a to 120d may be disposed on three surfaces of the passive devices 100a to 100d, respectively. Since the example embodiments of the present general inventive concept are easily understood with reference to FIGS. 1B and 1D, no additional drawings are provided. Specifically, the second dummy electrodes 135b and 135d may be other real electrodes. Each of the passive devices 100a to 100d may include at least one resistor, a least one capacitor, or at least one inductor. Each of the real dummy electrodes 120a to 120d and the first and second dummy electrodes 130a to 130d, 135b, and 135d may be formed in a fillet shape. The passive devices 100a to 100d may be devices to be mounted on semiconductor modules.

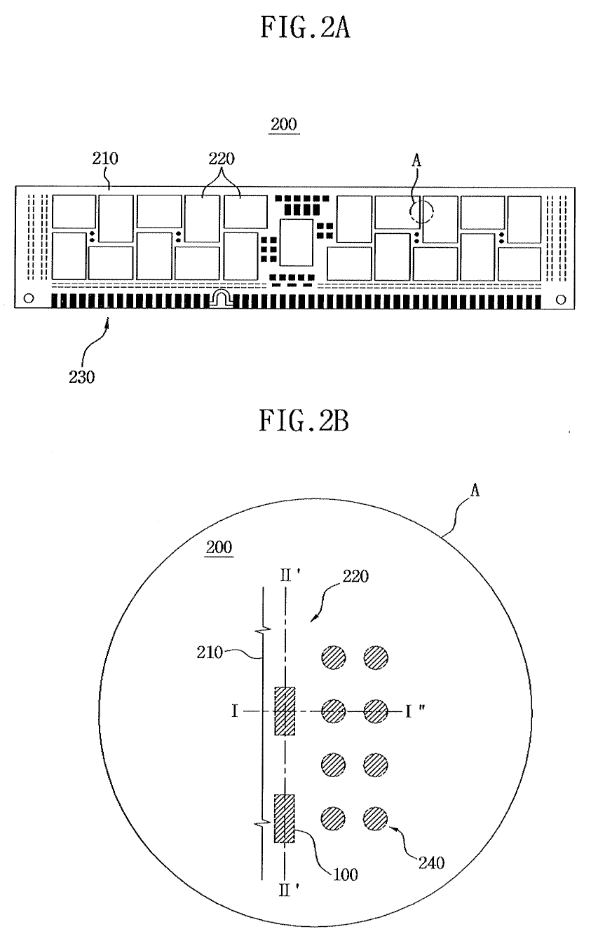

FIG. 2A illustrates a conceptual plan view of a semiconductor module according to example embodiments of the present general inventive concept. Referring to FIG. 2A, a semiconductor module 200 according to example embodiments may include a plurality of semiconductor packages 220 disposed on a module substrate 210 and a plurality of contact terminals 230 disposed on an edge of the module substrate 210. It may be understood that the semiconductor packages 220 are wafer-level packages, that is, in a wafer state, or may be any other suitable packages that carry out the exemplary embodiments of the present general inventive concept as described throughout. The contact terminals 230 may be portions of the module substrate 210, which are inserted into a module socket disposed on a circuit board of an electronic device. The contact terminals 230 may be media through which the semiconductor packages 220 externally receive and transmit electrical signals. Accordingly, the contact terminals 230 may be formed of a conductive material. Passive devices 110a to 110d according to example embodiments of the present general inventive concept may be selectively disposed on the module substrate 210. Since the passive devices 100a to 100d may be interleaved between the module substrate 210 and the semiconductor packages 220, the passive devices 100a to 100d may be hidden by the semiconductor packages 220 and are not illustrated in FIG. 2A, but are illustrated, for example, in FIG. 2B, as described below.

FIG. 2B illustrates an enlarged view of region A of the semiconductor module of FIG. 2A. Referring to FIG. 2B, a semiconductor module 200 according to example embodiments of the present general inventive concept may include passive devices 100 interleaved between the module substrate 210 and the semiconductor package 220. The module substrate 210 may be electrically or physically connected to the semiconductor package 220 by solders 240. The passive devices 100 may be electrically connected to conductive interconnections disposed on the module substrate 210. The passive devices 100 may be disposed on an outer portion of the semiconductor package 220. Since one or more of the solders 240 and the passive devices 100 may be hidden by the semiconductor package 220 and not illustrated, the one or more of the solders 240 and the passive devices 100 is illustrated with a dotted line.

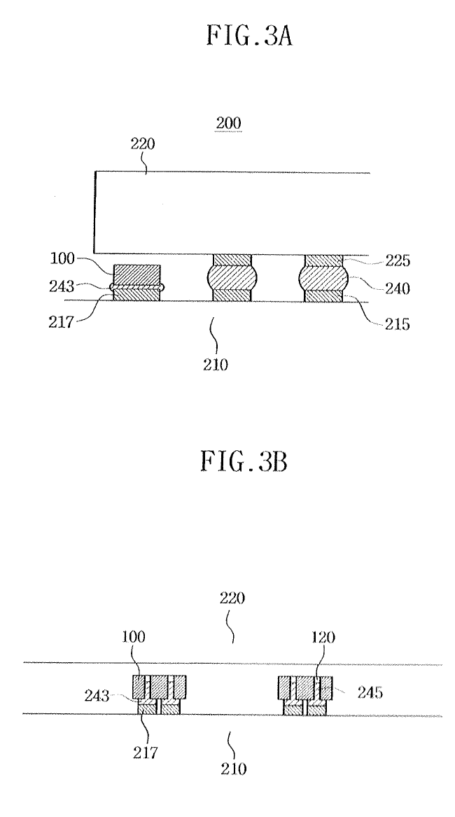

FIGS. 3A and 3B illustrate longitudinal sectional views taken along lines I-I′ and II-II′ of FIG. 2B. Referring to FIG. 3A, module interconnections 215 may be disposed on the module substrate 210, and solder bumps 225 may be disposed on a first surface of the semiconductor package 220. The module interconnections 215 may be electrically connected to the solder bumps 225 by the solders 240. The module interconnections 215 may be components to electrically connect the semiconductor packages 220 and the contact terminals 230 disposed on the module substrate 210. The module interconnections 215 may be spots where the solders 240 are disposed, for example, solder lands. The solder lands may be portions of the module interconnections 215 or conductive components electrically connected to the module interconnections 215. The module interconnections 215 and the solder lands terms may be interchangeably described for brevity. The passive device 100 may be disposed in a space between the module substrate 210 and the semiconductor package 220 where the solder bumps 225, the solders 240, and the module interconnections 215 are formed. For example, the passive device 100 may be disposed in the shadow of the semiconductor package 220. In other words, from the plan view, the passive device 100 of FIGS. 3A and 3B may not be seen with the naked eye. The passive device 100 may be physically and electrically connected to a passive device module interconnection 217 by a passive device solder 243. The passive device 100 may be spaced apart from the semiconductor package 220. The passive device module interconnection 217 is illustrated in a different shape from the module interconnections 215 only because it is unnecessary to make the passive device module interconnection 217 meet the same standard as the module interconnections 215. Accordingly, the passive device module interconnection 217 may have about the same size and shape as the module interconnections 215. The passive device solder 243 is illustrated to have a smaller thickness than the solders 240, and the passive device solder 243 and the solders 240 may be formed using different processes. Accordingly, the passive device solder 243 may be formed to have the same shape and/or thickness or about the same shape and/or thickness as the solders 240.

Referring to FIG. 3B, each of the passive devices 100 may include at least two real electrodes 120 disposed on a first lateral surface thereof, and the real electrodes 120 may be physically and electrically contacted by and connected to solder pillars 245. The solder pillars 245 may be portions of the passive device solders 243, which fill fillets of the real electrodes 120, respectively. Dummy electrodes (e.g., similar to the dummy electrodes 130a to 130d described above) may be formed on a second lateral surface of each of the passive devices 100, which is disposed opposite the first lateral surface on which the real electrodes 120 are formed. The dummy electrodes may be formed in the same shape or about the same shape as the real electrodes 120. The real electrodes 120 or the dummy electrodes may be formed along with solder pillars on lateral surfaces that are not disposed opposite the first lateral surface on which the real electrodes 120 are formed.

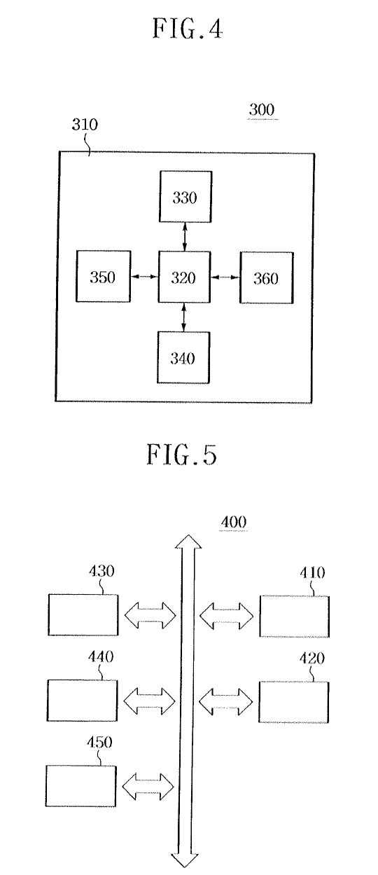

FIG. 4 illustrates a conceptual block diagram of an electronic circuit board according to example embodiments of the present general inventive concept. Referring to FIG. 4, an electronic circuit board 300 according to example embodiments may include a main processing circuit 320, a sub-processing circuit 330, and a memory circuit 340, which can be disposed on a base board 310. The electronic circuit board 300 may further include an input/output circuit 350 and/or a communication circuit 360. The main processing circuit 320 may include a microprocessor, central processing unit, a programmable gate array, or any other suitable processor to carry out the exemplary embodiments of the present general inventive concept as described throughout. The main processing circuit 320 may control electronic circuits and electronic components mounted on the base board 310. The sub-processing circuit 330 may receive electrical signals from the main processing circuit 320 and process data. For example, the sub-processing circuit 330 may include an image processor and/or a sound processor. The memory circuit 340 may include components to store data, for example, a dynamic random access memory (DRAM), a resistive RAM (RRAM), a flash memory, an optical disk drive (ODD), and/or a hard disk drive (HDD). The memory circuit 340 may include a passive device (e.g., passive devices 100a to 100d illustrated in FIGS. 1A-1D and described above) and/or a semiconductor module (e.g., semiconductor module 200 illustrated according to example embodiments of the present general inventive concept. The input/output circuit 350 may externally receive electrical signals and transmit the electrical signals to the main processing circuit 320 or receive electrical signals from the main processing circuit 320 and externally transmit the electrical signals. The communication circuit 360 may bi-directionally transmit electrical signals between the main processing circuit 320 and an external main processing circuit. The sub-processing circuit 330 may receive or transmit electrical signals from or to the input/output circuit 350. In FIG. 4, arrows indicate directions in which electrical signals can be transmitted.

FIG. 5 illustrates a conceptual block diagram of an electronic system according to example embodiments of the present general inventive concept. Referring to FIG. 5, an electronic system 400 according to example embodiments may include a central processing unit (CPU) 410, a memory unit 420, an input unit 430, and an output unit 440. The electronic system 400 may include a communication unit 450. For example, the electronic system 400 may be a personal or business computer, a mobile communication terminal, an exchanger, a moving picture player, a game player, or one of various other electronic products. The CPU 410 may control the electronic system 400 and perform active operations. For example, the CPU 410 may be a CPU of a computer or an application-specific integrated circuit (ASIC) or a microcomputer (MICOM) of a compact electronic product. The memory unit 420 may temporarily or permanently store electrical signals before or after the CPU 410 processes the electrical signals. For example, the memory unit 420 may include a semiconductor memory or a semiconductor module, which may include a DRAM, an RRAM, or a flash memory. Alternatively, the memory unit 420 may include a storage device, such as an ODD and/or an HDD. The input unit 430 may be an input apparatus that may be included in a computer, such as a mouse, a keyboard, a drawing pen, or a camera. Alternatively, the input unit 430 may be an input apparatus that may be included in a portable electronic device, such as a keypad, a touch pad, a stylus, and/or a camera. The output unit 440 may be a visual apparatus such as a monitor, a display, a printer, and/or a projector, an auditory apparatus such as a speaker, and/or a mechanical apparatus capable of mechanical operations. The communication unit 450 may be an apparatus for communicating with other electronic systems. For example, the communication unit 450 may be a modem, a wired and/or wireless local area network (LAN) card, a wireless broadband (WiBro) receiver, an infrared (IR) port, and/or a power delivery apparatus. The arrows may refer to buses and/or channels of the electronic system 400 along with data and/or electrical signals may travel.

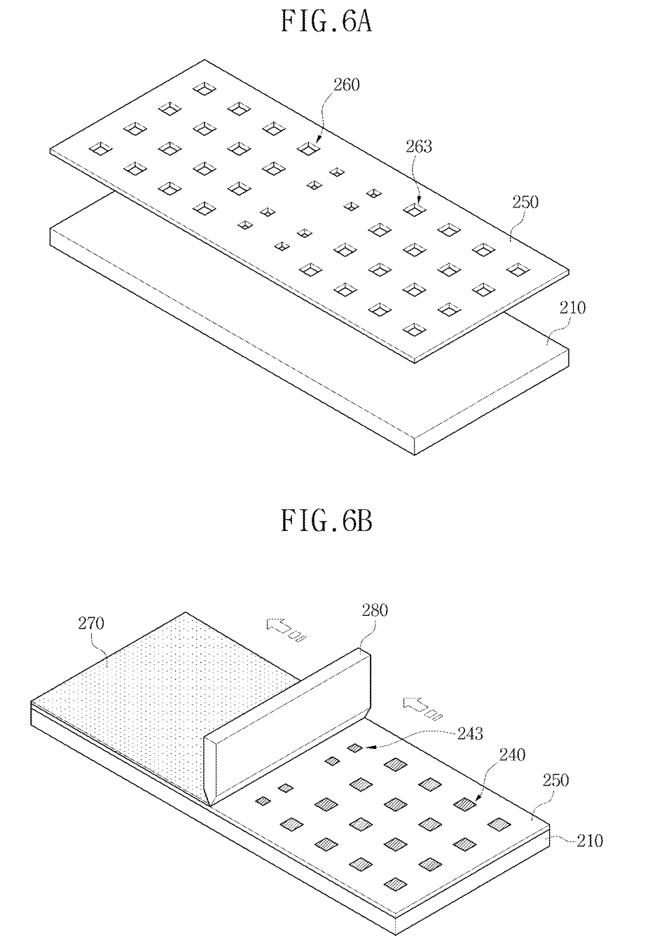

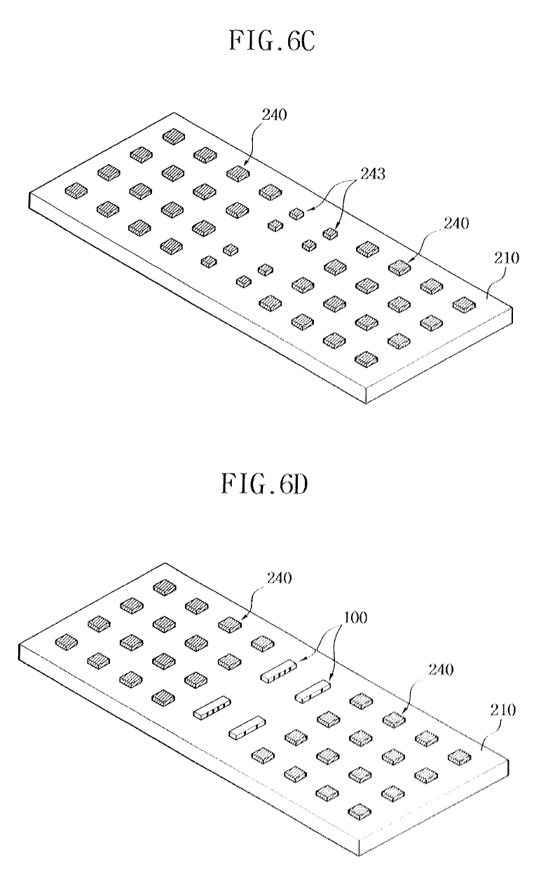

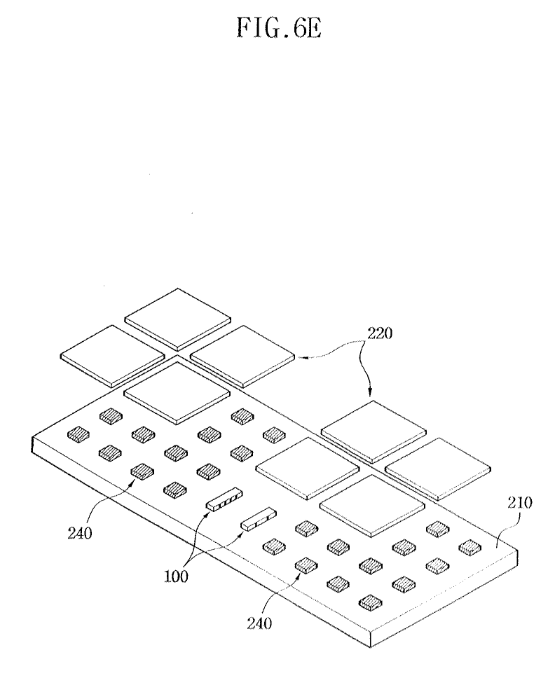

Hereinafter, processes of fabricating a semiconductor module according to example embodiments of the present general inventive concept will be briefly described. FIGS. 6A through 6E are schematic diagrams illustrating a process of fabricating a semiconductor module according to example embodiments. Referring to FIG. 6A, a module substrate 210 may be prepared. A screen 250 having solder holes 260 and 263 may be provided over the module substrate 210. Although the module substrate 210 having module interconnections may be provided, illustrations of the module interconnections are omitted from the drawings for brevity. The solder holes 260 and 263 may be components having information on the positions of solders to be formed on the module substrate 210. The solder holes 260 and 263 may include semiconductor-package connection solder holes 260 and passive-device connection solder holes 263. The screen 250 may be a stencil film, that is, a thin film having a plurality of holes.

Referring to FIG. 6B, the screen 250 may be adhered onto the module substrate 210, a conductive material 270 in a liquid or gel form may be dispensed and/or squeezed using a milling blade 280 or a roller so that the solder holes 260 and 263 may be filled with the conductive material 270 to form solders 240 and 243.

Referring to FIG. 6C, the screen 250 may be removed, and the solders 240 and 243 may be formed on the module substrate 210. The solders 240 and 243 may include the semiconductor-package connection solders 240 and the passive-device connection solders 243.

Referring to FIG. 6D, passive devices 100 may be disposed on the passive-device connection solders 243. The passive devices 100 may be placed on the passive-device connection solders 243, and heated and bonded onto the passive-device connection solders 243. In this case, portions of the passive-device connection solders 243 may melt and rise along fillet-shaped electrodes of the passive devices 100. In this process, the passive devices 100 may be strained due to a reduction in volumes of the passive-device connection solders 243. Specifically, the passive devices 100 may be attracted to the solders 243. When no electrodes are formed on second lateral surfaces of the passive devices 100 other than first lateral surfaces on which the electrodes are formed, the passive devices 100 may not remain in equilibrium but may lean toward a strained direction. However, the passive devices 100 according to the present general inventive concept may include electrodes formed on second lateral surfaces disposed opposite first lateral surfaces on which electrodes are formed. More specifically, real electrodes (e.g., real electrodes 120a to 120d as illustrated in FIGS. 1A-1D and described above) may be formed on first lateral surfaces of the passive devices 100, while dummy electrodes (e.g., dummy electrode 130a to 130d as illustrated in FIGS. 1A-1D and described above) may be formed on second lateral surfaces disposed opposite the first lateral surfaces. Thus, during a bonding process, the passive devices 100 may be prevented from leaning toward the first lateral surfaces on which the electrodes are formed (and/or the leaning of the passive device 100 toward the first lateral surfaces may be minimized).

Referring to FIG. 6E, semiconductor packages 220 may be bonded onto the semiconductor-package connection solders 240. Since the semiconductor packages 220 may not have fillets, a reduction in volumes of the semiconductor-package connection solders 240 may be minimized and/or prevented, and fabrication of a semiconductor module 200 according to the present general inventive concept may be completed. According to the present general inventive concept, the passive devices 100 may be disposed on outer portions of the semiconductor packages 220. During the process of bonding the semiconductor packages 220 onto the semiconductor-package connection solders 240, at least some stress applied to outer portions of the semiconductor packages 220 may be shared with the passive devices 100. Not only during the bonding process but also during subsequent processes of transporting, assembling, and employing the semiconductor module 200, at least some of the physical stress applied to the semiconductor packages 200 may be shared with the passive devices 100. In other words, the semiconductor packages 220 and the semiconductor modules 200 may become more physically durable.

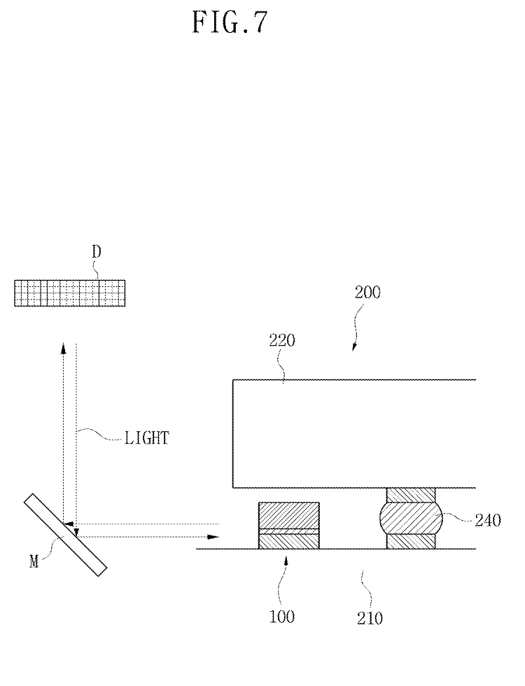

FIG. 7 illustrates a longitudinal sectional view of a process operation of a process of inspecting a semiconductor module according to example embodiments of the present general inventive concept. Referring to FIG. 7, when a semiconductor package 220 is bonded and fixed onto a solder 240, physical connection states of passive devices 100 of a semiconductor module 200 according to example embodiments may be visually inspected using an optical apparatus. According to the present general inventive concept, real electrodes may be formed only on one lateral surface of each of the passive devices 100. Thus, by inspecting any one lateral surface of each of the passive devices 100, all physical connection states of electrodes of the passive devices 100 may be inspected. Light reflected by one lateral surface of each of the passive devices 100 may be reflected by a mirror M and collected by a light receiving unit D. The light receiving unit D may be an ocular unit to inspect the physical connection states of electrodes of the passive devices 100. When real electrodes are formed even on other lateral surfaces of the passive device 100, the process of inspecting the physical connection states of the passive devices 100 may not be performed, or may be increasingly difficult to perform, after the semiconductor package 220 is bonded and fixed onto the solder 240.

The terms and functions of components that are not denoted by reference numerals in the drawings may be easily understood with reference to other drawings and their descriptions of the present specification.

As described above, in a passive device, a semiconductor module, an electronic circuit board, and an electronic system according to example embodiments, passive devices may be interleaved between a module substrate and a semiconductor module so that the passive device may not be seen from the plan view. Thus, the integration density of the semiconductor module may be increased, thereby reducing the unit cost of production. Since both electrical connection states and physical fixing states of passive devices may be inspected using a lateral visual inspection process, fabrication and inspection processes may be simplified, thereby improving productivity.

While several example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

1. A passive device of a semiconductor module, comprising:
a main body; and
at least two real electrodes disposed on a first lateral surface of the main body.

2. The device of claim 1, wherein each of the real electrodes has a fillet shape.

3. The device of claim 1, further comprising:
at least one dummy electrode disposed on a second lateral surface of the main body disposed opposite the first lateral surface thereof.

4. The device of claim 3, wherein the dummy electrode has a fillet shape.

5. The device of claim 3, wherein the real electrodes are electrically connected to one another, and the dummy electrode is not electrically connected to the real electrodes.

6. The device of claim 1, wherein the real electrodes are not disposed on lateral surfaces of the main body other than the first lateral surface thereof.

7. A passive device of a semiconductor module, comprising:
a main body;
at least two real electrodes disposed on a first lateral surface of the main body, each real electrode having a fillet shape; and
at least one dummy electrode disposed on a second lateral surface of the main body disposed opposite the first lateral surface thereof, and having a fillet shape,
wherein the real electrodes are electrically connected to one another, and the dummy electrode is not electrically connected to the real electrodes.

8. The passive device of a semiconductor of claim 7, wherein two of the real electrodes are electrically connected to each other, and the dummy electrode is not electrically connected to the real electrodes.

9.-21. (canceled)

22. A passive device of a semiconductor module, comprising:
a main body; and
a plurality of real electrodes disposed in channels of a first surface of the main body and electrically connected to one another.

23. The passive device of claim 22, further comprising:
at least one dummy electrode disposed in the at least one channel of a second surface of the main body that is opposite the first surface, wherein the at least one dummy electrode is not electrically connected to the plurality of real electrodes.

24. (canceled)
